(19) United States
(12) Patent Application Publication
(10) Pub. No.: US 2024/0127407 A1
(43) Pub. Date: Apr. 18, 2024

(54) IMAGE SENSOR APPARATUS FOR CAPTURING DEPTH INFORMATION

(71) Applicant: CISTA SYSTEM CORP., Grand Cayman (KY)

(72) Inventors: Zhaojian LI, FREMONT, CA (US); Jiangtao PANG, FREMONT, CA (US)

(21) Appl. No.: 17/968,573

(22) Filed: Oct. 18, 2022

(51) Int. Cl. G06T 5/00; G06T 3/40; G06T 7/00; G06T 7/194; G06T 7/536

(52) U.S. Cl. CPC G06T 5/002; G06T 3/4015; G06T 3/4053; G06T 7/194; G06T 7/536; G06T 7/97; G06T 2207/10024; G06T 2207/10028

(57) ABSTRACT

This application describes apparatuses and systems for rendering the Bokeh effect using multi-pixel microlenses. An example apparatus includes a pixel array including a plurality of pixel groups, each pixel group having a square shape comprising at least four pixels, wherein: each pixel group is covered by a microlens; each pixel group is configured with color filters of a same color such that pixels covered by the pixel group capture the same color; and every four adjacent pixel groups form a two-by-two matrix and the four adjacent pixel groups include at least three pixel groups configured with color filters of three different colors.

### TECHNICAL FIELD

The disclosure relates generally to an apparatus and method for capturing depth information using a single sensor with multi-pixel microlenses.

### BACKGROUND

The Bokeh effect is used in photography to produce images where the closer objects look sharp and everything else stays out-of-focus. Depth mapping that identifies the background and the foreground is the core of Bokeh effect production. Most modern cameras, smartphones, or other devices obtain depth information by leveraging multiple image sensors, such as dual-camera configurations. These image sensors effectively form a stereo camera that simulates human binocular vision to perceive depth information. This disclosure describes a single image sensor with multi-pixel microlenses for capturing depth information and thereby facilitating the rendering of the Bokeh effect to the images.

### SUMMARY

Various embodiments of this specification may include hardware circuits, systems, and methods related to capturing depth information for rendering the Bokeh effect.

In some aspects, the techniques described herein relate to an image sensor apparatus, including: a pixel array including a plurality of pixel groups, each pixel group having a square shape including at least four pixels, each pixel group being covered by a microlens with a curved surface and configured with color filters of a same color such that pixels in the pixel group capture the same color, wherein pixels in each pixel group capture different views of a scene as a result of refractions at the curved surface of the microlens; and one or more processors electrically coupled to the pixel array and configured to: compute a depth map of the scene based on the different views of the scene; and render bokeh-effect to the scene based on the depth map.

In some aspects, every four adjacent pixel groups form a two-by-two matrix and the four adjacent pixel groups include at least three pixel groups configured with color filters of three different colors.

In some aspects, the plurality of pixel groups are configured with color filters arranged in a Bayer pattern such that every two-by-two matrix of pixel groups includes two pixel groups configured with green filters, one pixel group configured with red filters, and one pixel group configured with blue filters.

In some aspects, the one or more processors are further configured to execute a resolution restoration algorithm to restore resolution loss caused by using multiple pixels in each pixel group to capture a same color.

In some aspects, each pixel group includes two-by-two pixels, and the different views include a top-left view, a top-right view, a bottom-left view, and a bottom-right view.

In some aspects, to compute the depth map, the one or more processors are further configured to: compute the depth map based on one or more combinations of two views from the top-left view, the top-right view, the bottom-left view, and the bottom-right view.

In some aspects, to compute the depth map, the one or more processors are further configured to: obtain a left view and a right view from the top-left view, the top-right view, the bottom-left view, and the bottom-right view as two views in stereo vision; determine a disparity between the left view and the right view; and generate depth information based on the disparity and position information of the pixels that captured the left view and the right view.

In some aspects, to compute the depth map, the one or more processors are further configured to: obtain a top view and a bottom view from the top-left view, the top-right view, the bottom-left view, and the bottom-right view as two views in stereo vision; determine a disparity between the top view and the bottom view; and generate depth information based on the disparity and position information of the pixels that captured the top view and the bottom view.

In some aspects, to render bokeh-effect based on the depth map, the one or more processors are configured to: determine a foreground and a background of the scene; and performing linear filtering or non-linear filtering to blur the background of the scene depending on the depth of the background.

In some aspects, the image sensor apparatus is a smartphone camera.

In some aspects, the techniques described herein relate to an image sensor apparatus, including: a pixel array including a plurality of pixel groups, each pixel group having a square shape including at least four pixels, wherein: each pixel group is covered by a microlens; each pixel group is configured with color filters of a same color such that pixels in the pixel group capture the same color; and every four adjacent pixel groups form a two-by-two matrix and the four adjacent pixel groups include at least three pixel groups configured with color filters of three different colors.

In some aspects, the pixels in the pixel group are configured to capture different views of a scene as a result of refractions at a curved surface of the microlens; and the image sensor apparatus further includes: one or more processors configured to compute depth information based on the different views captured by the pixels covered by the same microlens.

In some aspects, the different views include a top-left view, a top-right view, a bottom-left view, and a bottom-right view.

In some aspects, to compute the depth information, the one or more processors are further configured to: compute the depth information based on one or more combinations of two views from the top-left view, the top-right view, the bottom-left view, and the bottom-right view.

In some aspects, the one or more processors are further configured to: render bokeh-effect based on the depth information.

In some aspects, to render bokeh-effect based on the depth information, the one or more processors are configured to: determine a foreground and a background of the scene; and performing linear filtering or non-linear filtering to blur the background of the scene depending on a depth of the background.

In some aspects, the square shape includes a side dimension of t, where t is equal to or greater than two.

In some aspects, the microlens includes a curved surface and a plane surface, and the pixels in the pixel group covered by the microlens are evenly distributed under the plane surface.

In some aspects, the plurality of pixel groups are configured with color filters arranged in a Bayer pattern such that every two-by-two matrix of pixel groups includes two pixel groups configured with green filters, one pixel group configured with red filters, and one pixel group configured with blue filters.

In some aspects, the image sensor apparatus further includes one or more processors configured to execute a resolution restoration algorithm to restore resolution loss caused by using multiple pixels in each pixel group to capture a same color.

These and other features of the systems, methods, and hardware devices disclosed, and the methods of operation and functions of the related elements of structure and the combination of parts and economies of manufacture will become more apparent upon consideration of the following description and the appended claims referring to the drawings, which form a part of this specification, where like reference numerals designate corresponding parts in the figures. It is to be understood, however, that the drawings are for illustration and description only and are not intended as a definition of the limits of the invention.

### BRIEF DESCRIPTION OF THE DRAWINGS

FIG. 1 illustrates an example layout of single-pixel microlenses in an image sensor and an example layout of quad-pixel microlenses in another image sensor, according to some embodiments of this specification.

FIG. 2 illustrates an exemplary quad-pixel microlens capturing multiple angle views, according to some embodiments of this specification.

FIG. 3A illustrates an exemplary workflow for rendering the Bokeh effect using a single image sensor with quad-pixel microlenses, according to some embodiments of this specification.

FIG. 3B illustrates another exemplary workflow for rendering the Bokeh effect using a single image sensor with quad-pixel microlenses, according to some embodiments of this specification.

FIG. 3C illustrates a comparison between a dual-image-sensor configuration and a single image sensor configured with quad-pixel microlenses for capturing depth information, according to some embodiments of this specification.

FIG. 4 is a schematic diagram of an example image sensor with quad-pixel microlenses for rendering the Bokeh effect, according to some embodiments of this specification.

### DETAILED DESCRIPTION

The specification is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present specification. Thus, the specification is not limited to the embodiments shown but is to be accorded the widest scope consistent with the principles and features disclosed herein.

Digital cameras, scanners, and other imaging devices often use image sensors, such as charge-coupled device (CCD) image sensors or complementary metal-oxide semiconductor (CMOS) image sensors, to convert optical signals to electrical signals. An image sensor can typically include a grid of pixels (referring to photodiodes or photosites in this disclosure), row access circuitry, column access circuitry, and a ramp signal generator. The pixels capture the light impinged on them and convert the light signals to electrical signals. The row access circuitry controls which row of pixels the sensor will read. The column access circuitry includes column read circuits that read the signals from corresponding columns. The ramp signal generator generates a ramping signal as a global reference signal for column read circuits to record the converted electrical signal.

The imaging devices for capturing colored images may also include a color filter array (CFA) or color filter mosaic (CFM), which is a mosaic of tiny color filters placed over the pixels of the image sensor to capture color information. The color filters filter the light by wavelength range, such that the separate filtered intensities include information about the color of light. For example, a Bayer pattern CFA gives information about the intensity of light in red, green, and blue (RGB) wavelength regions. The raw image data captured by the image sensor is then converted to a full-color image (with intensities of all three primary colors represented at each pixel) by a demosaicing algorithm which is tailored for each type of color filter. The spectral transmittance of the CFA elements along with the demosaicing algorithm jointly determine the color rendition.

The imaging devices may further include a plurality of microlenses covering the pixels. A microlens is a small lens, generally with a diameter less than a millimeter (mm) and could be less than 2 micrometers (μm) when pixel size scales below 2 μm. A typical microlens may be a single element with one plane surface and one spherical convex surface to refract the light. The plurality of microlenses are sometimes arranged as an array, such as a one-dimensional or two-dimensional array on a supporting substrate. Single micro-lenses may be used to couple light to the covered pixels or photodiodes; microlens arrays may be used to increase the light collection efficiency of CCD arrays and CMOS sensors, to collect and focus light that would have otherwise fallen onto the non-sensitive areas of the sensors.

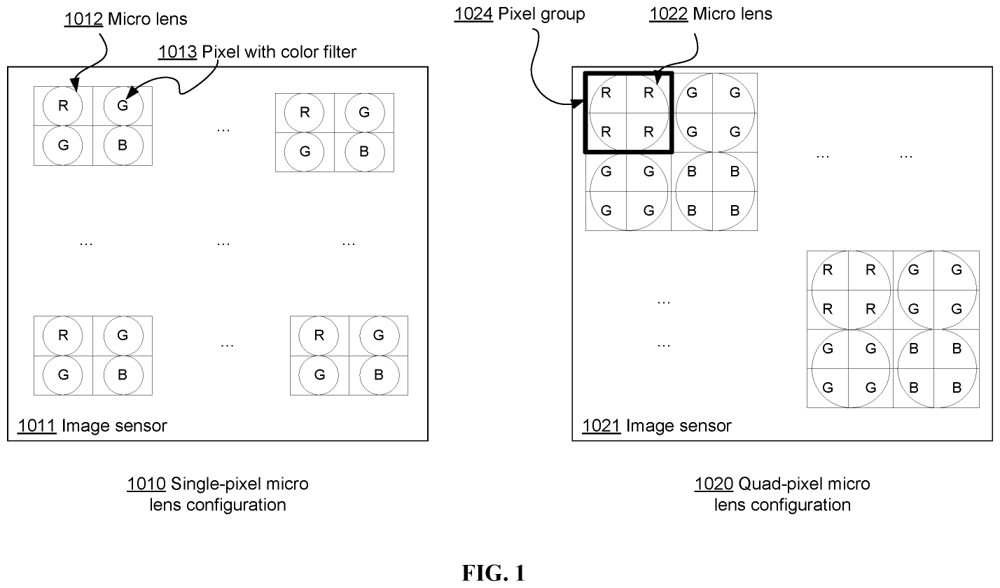

FIG. 1 illustrates an example layout of single-pixel microlenses in an image sensor 1011 and an example layout of quad-pixel microlenses in another image sensor 1021, according to some embodiments of this specification. The image sensors may refer to various types of image-capturing devices, such as smartphone cameras. In some cases, these image sensors may be equipped with data processing resources to process the captured image data.

In the single-pixel microlens configuration 1010, the pixels in the image sensor 1011 are respectively covered by microlenses 1012 for coupling lights to the covered pixels. To capture colored images, the pixels are also covered by a CFA following the Bayer pattern, in which half of the CFA are green filters, one quarter of the CFA are red filters, and one quarter of the CFA are blue filters. This CFA configuration may be referred to as RGGB. Alternatives to the Bayer pattern including RGBW, RYYB, CYYM, etc. may also be adopted to implement the disclosed technology. The CFA may be configured underneath the microlenses 1012.

As an example shown in FIG. 1, each pixel 1013 of the image sensor 1011 is covered with a color filter and a microlens 1012 (thus called single-pixel microlens). The color filters (e.g., CFA) may be arranged in the Bayer pattern, in which every two by two pixels are covered by one red filter, two green filters, and one blue filter. With the microlenses, the pixels 1013 capture the intensity of the light impinged on them and convert the light signals to electrical signals that are transferred through a transfer gate. In this single-pixel microlens configuration 1010, the pixels 1013 (e.g., the two-by-two pixel group at the top left) have small sizes at the millimeter or micrometers level and the neighboring pixels 1013 are physically next to each other. Thus, these neighboring pixels 1013 are likely to share highly analogous views of a source of light or a target object. In other words, the information captured by the pixels 1013 in the image sensor 1011 may be insufficient to provide angle information of the source of light or the target object. Multiple image sensors 1011 may be required to form the stereo vision configuration in order to obtain the depth information.

In comparison, the quad-pixel microlens configuration 1020 in FIG. 1 shows an image sensor 1021 in which one microlens 1022 is configured to cover a two-by-two matrix of pixels 1024 (also called a pixel group), and the pixels in the pixel group 1024 are covered with color filters of the same color. For instance, the top-left pixel group 1024 includes four pixels, each being equipped with a red color filter (e.g., the red color filter may be placed above the pixel but below a corresponding microlens covering the pixel group); the neighboring pixel group on the right also includes four pixels, each being equipped with a green color filter; the neighboring pixel group below it also includes four pixels, each being equipped with a green color filter; and the diagonal neighboring pixel group also includes four pixels, each being equipped with a blue color filter. With this configuration, each microlens 1022 covers each pixel group, the pixels covered by each microlens 1022 are evenly distributed underneath the microlens and capture the same color, and multiple pixel groups (e.g., a two-by-two matrix of pixel groups including four adjacent pixel groups) may be configured with color filters following the Bayer pattern.

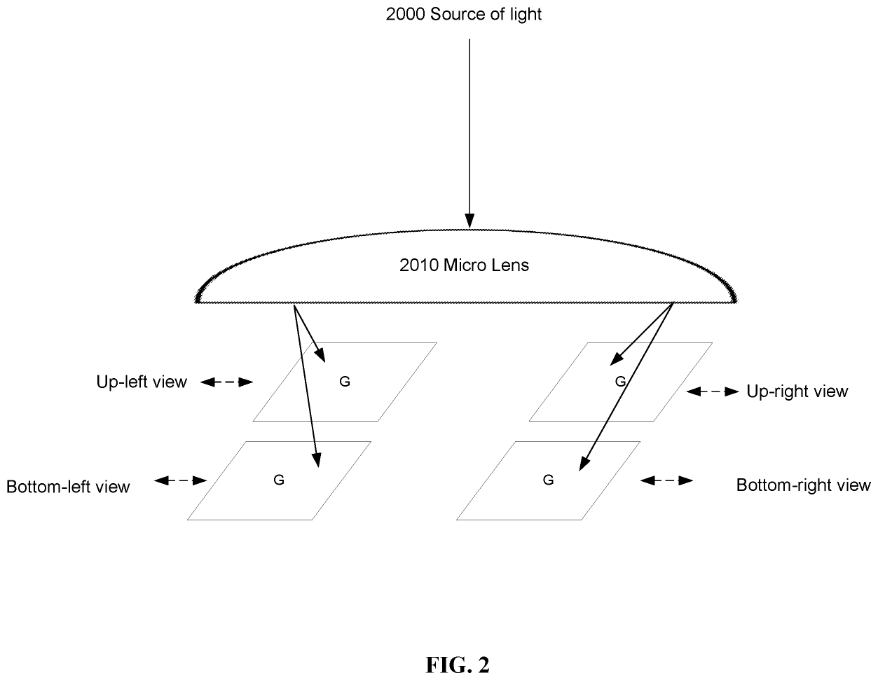

The quad-pixel microlens configuration 1020 demonstrates several different characteristics than the single-pixel microlens configuration 1010. First, because the curvature of the microlens surface causes refractions of light, the pixels underneath the microlens surface may receive the source of light with different angle views due to the refractions (more details in FIG. 2). These different angle views may be used to extract angle information and subsequently determine the depth information for rendering the Bokeh effect. Second, the pixels in each pixel group 1024 are configured with color filters of the same color, which means the pixel group 1024 as a whole is used to identify a color signal, instead of using each pixel. In summary, the first difference provides a benefit that allows the pixels to capture different angle information, which makes it possible to construct the depth map directly using the single image sensor 1021. On the other hand, the second difference may potentially lower the resolution of the image produced by the image sensor, which may be remedied by using full-size, full-color reconstruction algorithms. An example reconstruction algorithm includes bilinear or bicubic interpolation based on the estimated edge direction. Some other methods exploit the color correlation of pixels such as alternating projection method.

Note that the quad-pixel microlens configuration 1020 is for illustrative purposes. Depending on the implementation, each microlens 1022 may cover a square shape of pixel group with a side dimension of t, t being equal to or greater than two (e.g., each microlens 1022 may cover a three-by-three pixel group or four-by-four pixel group).

FIG. 2 illustrates an exemplary quad-pixel microlens 2010 capturing multiple angle views, according to some embodiments of this specification. The microlens 2010 has a plane surface and a curved surface, e.g., a spherical surface. When the microlens 2010 covers multiple pixels and these pixels are distributed not in the center of the microlens 2010, the source of light 2000 impinged on the microlens 2010 may go through refractions before landing on the underlying pixels. This refraction process allows the underlying pixels to capture the source of light 2000 from different view angles. For instance, if the microlens 2010 is a quad-pixel microlens (covering two-by-two pixels), the underlying four pixels may capture four different views from four different angles caused by the refractions. The views may be referred to as top-left view, top-right view, bottom-left view, and bottom-right view, respectively.

With this configuration, the pixels covered by the microlens 2010 capture not only the color intensities of the filtered color (e.g., “G” stands for the green color in FIG. 2) in the source of light, but also different views that inherently contain angle information. This angle information may later be used to construct the depth map, which may then be used for rendering the Bokeh effect.

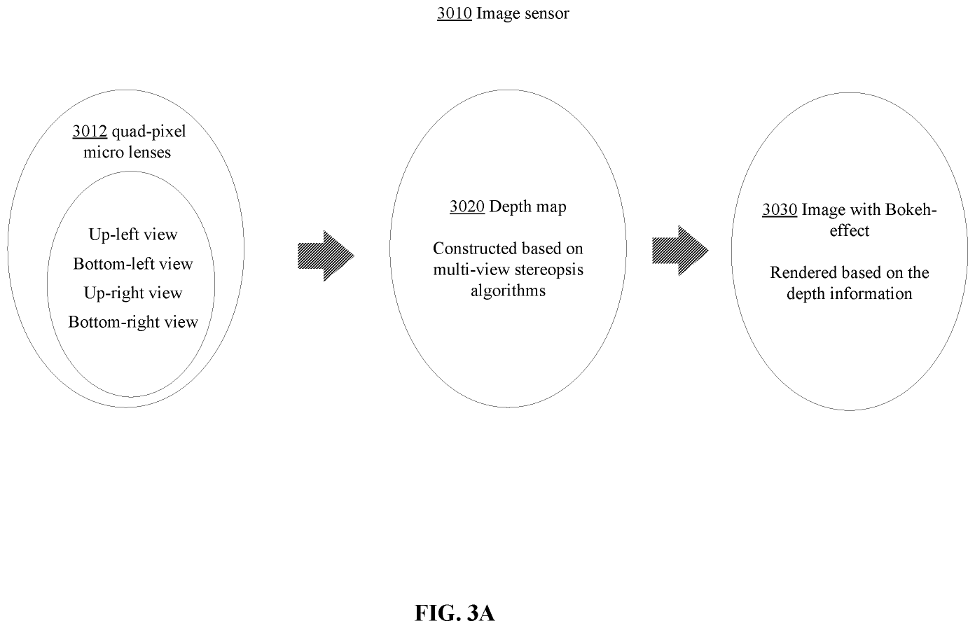

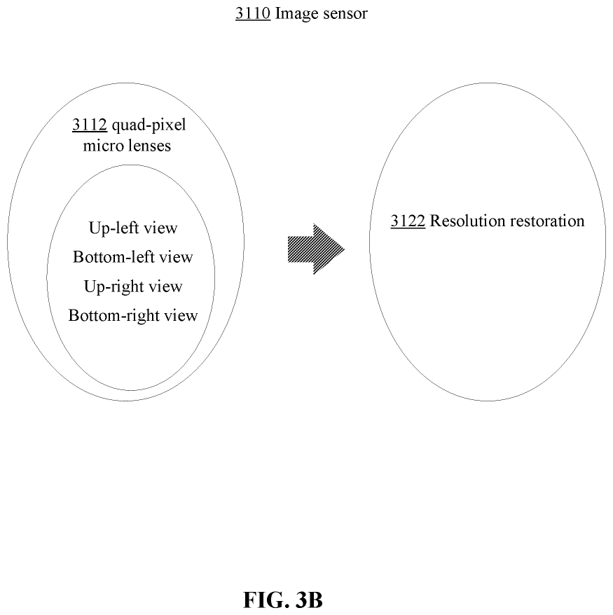

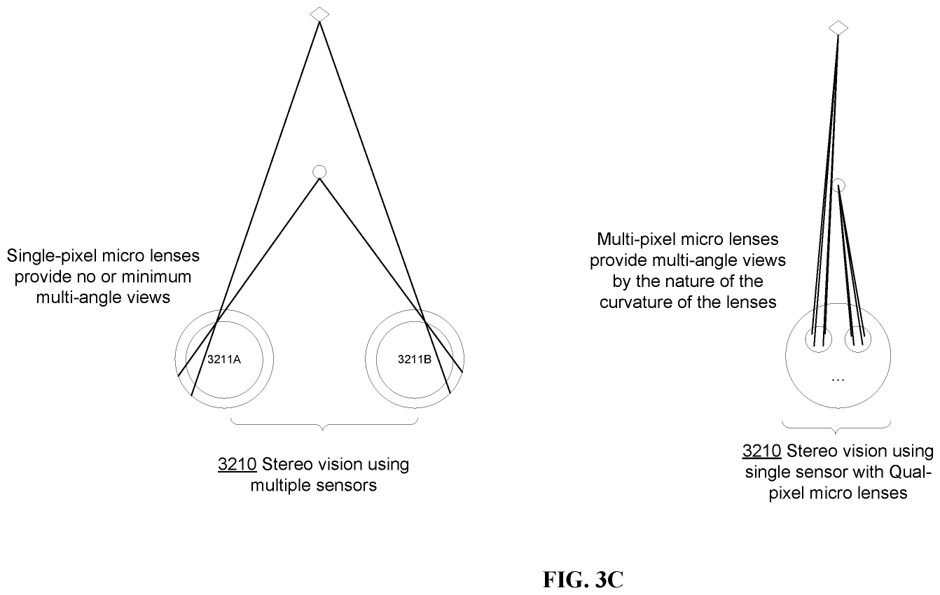

FIG. 3A illustrates an exemplary workflow for rendering the Bokeh effect using a single image sensor 3010 with quad-pixel microlenses, according to some embodiments of this specification. The workflow includes a process of using the single image sensor 3010 to capture different views of an image using quad-pixel microlenses 3012, constructing a depth map 3020 based on the different views, and rendering the Bokeh effect 3030 to the image based on the depth map 3020.

In some embodiments, the image sensor 3010 may include a pixel array (e.g., millions of pixels) and a plurality of microlenses 3012. The pixel array may be segmented into a plurality of pixel groups. For instance, if each pixel group includes four pixels (i.e., a two-by-two square of pixels) and is covered by one microlens, the microlens may be referred to as quad-pixel microlens 3012. Within each pixel group, the pixels are further covered with color filters of the same color. The plurality of pixel groups may be further configured to follow the Bayer pattern, in which every two-by-two matrix of pixel groups are configured with color filters of mixed colors, e.g., RGGB pattern. Each microlens 3012 covering one pixel group has a plane surface and a curved surface, e.g., a spherical surface. The pixels within the covered pixel group may be evenly distributed on a plane that is in parallel with the plane surface of the microlens 3012. Because the curved surface of the microlens 3012 causes refraction of the impinged light, the evenly distributed pixels underneath the microlens are able to capture the light from different view angles as a result of the refractions. For instance, the image sensor 3010 with qua-pixel microlenses 3012 may capture, at each microlens 3012, an top-left view, a bottom-left view, an top-right view, and a bottom-right view of a given source of light. These views carry angle information that can be used to derive depth information of the light.

In some embodiments, the image sensor 3010 may further include one or more processors such as accelerators implemented with Application Specific Integrated Circuit (ASIC) or field programmable gate array (FPGA) to perform various computations. In other embodiments, the one or more processors may be configured outside of the image sensor 3010 that processes the data provided by the image sensor 3010.

The processors may fetch the different angle views captured by the quad-pixel microlenses 3012 to extract the angle information and construct a depth map 3020. Multi-view stereopsis algorithms may be executed to construct the depth map 3020. The different angle views from the pixels covered by the quad-pixel microlenses effectively form a stereo vision, and the depth information may be obtained based on one or more combinations of two views from the top-left view, the top-right view, the bottom-left view, and the bottom-right view captured by each pixel group. For instance, the top-left view and the top right view from the pixels of the same pixel group may be used to derive the depth information in the horizontal dimension; and the top-left view and the bottom left view from the pixels of the same pixel group may be used to derive the depth information in the vertical dimension. Here, the depth map 3020 may refer to an image or image channel that contains information relating to the distance of the surfaces of scene objects from a viewpoint, or another form of a data structure containing the depth information of the objects from the viewpoint. The “stereopsis” refers to perceiving depth based on different perspectives of the target object or environment.

For instance, the one or more processors may construct the depth map 3020 from the collection of views from the pixels with known pixel poses and calibration by, as an example, computing plane-sweep volumes and optimizing photometric consistency with error functions to measure similarities and disparities between patches. Aside from photometric consistency, other 3D cues such as lighting, shadows, color, geometric structures, and semantic cues may also be considered to improve reconstruction accuracy. As another example, the depth map 3020 may be constructed using a deep convolutional neural network (ConvNet) designed to learn patch similarities and disparities for stereo matching.

In some embodiments, the one or more processors may subsequently render the Bokeh effect 3030 to the output image based on the depth information in the depth map 3020. The depth information reveals the foreground and background of the image. The Bokeh effect 3030 may be rendered by blurring the background image. This step may be implemented using linear filtering, such as mean filtering, Gaussian filtering; or nonlinear filtering, such as bilateral filtering, median filtering. In a particular case, the foreground target in the image is identified to select the focal plane, the blur radius of different regions in the image is then calculated according to the depth map and the focal plane, and finally a refocused image is generated based on the blur radius that meets the human aesthetic and bokeh-effect characteristics (e.g., the farther the objects are from the focal plane, the more blurred they are.).

FIG. 3B illustrates another exemplary workflow for rendering the Bokeh effect using a single image sensor 3110 with quad-pixel microlenses, according to some embodiments of this specification. The image sensor 3110 may include hardware resources and software pipelines to implement the functionalities performed by the image sensor 3010 as described in FIG. 3A. In addition, the image sensor 3110 may further restore the resolution loss caused by the quad-pixel microlenses 3112 or other types of multi-pixel microlenses. As explained above, since the quad-pixel microlenses 3112 group the pixels into pixel groups and cover the pixels within the same pixel group with color filters of the same color, the resolution of the output image is effectively reduced by the factor of 4 (e.g., using a 4-pixel group to capture color information of the same color rather than using 4 contiguous pixels to capture different RGB colors).

To address this issue, the image sensor 3110 may be configured with or coupled with one or more processors to perform the resolution restoration 3122 to restore the resolution, such as bilinear or bicubic interpolation based on the estimated edge direction.

FIG. 3C illustrates a comparison between a dual-image-sensor configuration and a single image sensor configured with quad-pixel microlenses for capturing depth information, according to some embodiments of this specification.

As shown on the left portion of FIG. 3C, the stereo vision 3210 obtained using single-pixel microlenses may require multiple image sensors, e.g., image sensors 3211A and 3211B, to capture the target object from different view angles. Here, a single-pixel microlens refers to a microlens that covers only one pixel, and the one pixel is placed at the center of the plane surface of the microlens. With this configuration, the contiguous pixels may receive lights that have gone through a same or analogous refraction process, and thus provide the same or analogous angle views of the source of light or the target object. Thus, to obtain multi-angle views, multiple image sensors may be needed. These views captured by the multiple image sensors along with the location information of the multiple image sensors may be used to learn the angle information as well as the depth map.

In comparison, as shown on the right portion of FIG. 3C, the multi-pixel microlenses may enable a single image sensor to capture multi-angle views by placing multiple pixels under the same microlens. Since the microlens' curved surface refracts the incoming light, the pixels at different positions under the microlens may receive different angle views from the same source of light. With these multi-angle views, the single image sensor may derive the depth information for rendering the Bokeh effect.

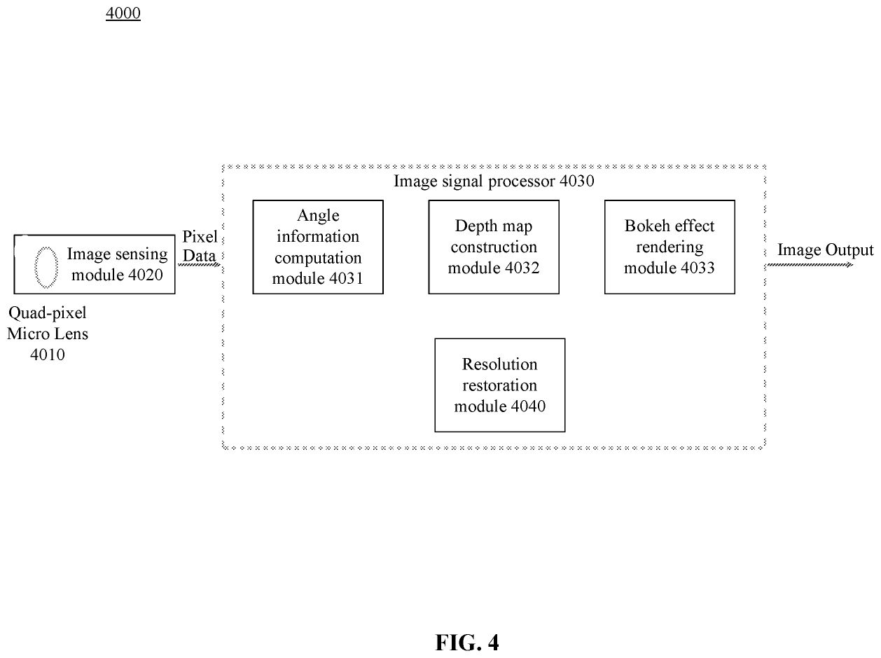

FIG. 4 is a schematic diagram of an example image sensor apparatus 4000 with quad-pixel microlenses for rendering the Bokeh effect, according to some embodiments of this specification. The schematic diagram in FIG. 4 is for illustrative purposes only, and an image sensor apparatus 4000 shown in FIG. 4 may have fewer, more, and alternative components and connections depending on the implementation.

As shown in FIG. 4, image sensor apparatus 4000 can include an image sensing module 4020 and one or more image signal processors 4030. In some embodiments, the image sensing module 4020 may include a plurality of pixels (also called a pixel array) and a plurality of quad-pixel microlenses 4010 to capture a target image. The resolution of the target image may be proportional to the number of pixels in the image sensor. The plurality of pixels may be segmented into a plurality of pixel groups, each pixel group including multiple pixels (e.g., two-by-two pixels). Each of the plurality of quad-pixel microlens covers one pixel group. The microlens includes a spherical surface and a plane surface. The pixels in the pixel group are even positioned under the microlens along the plane surface. Because of the light refractions on the spherical surface of the microlens, the pixels underneath the microlens are configured to obtain multi-angle views of a source of light. The pixels covered by the same microlens may be further configured with color filters of the same color; and the pixels from two horizontally adjacent pixel groups (covered by two microlenses respectively) may be configured with color filters of two different colors. This way, the pixels from the same pixel group may capture the light intensities of the same color in the source of light from multiple angle views (due to the refraction); and the pixel groups are equipped with color filters arranged in the Bayer pattern such that every two-by-two matrix of pixel groups comprises two pixel groups configured with green filters, one pixel group configured with red filters, and one pixel group configured with blue filters. The pixels here may refer to photodiodes for receiving light signals and converting light signals to electronic signals.

The image signal processor 4030 may be configured to process the multi-angle views captured by the image sensing module 4020 and generate an output image with the Bokeh effect. In some embodiments, the image signal processor 4030 may include various modules, such as angle information computation module 4031, depth map construction module 4032, Bokeh effect rendering module 4033, and resolution restoration module 4040. Depending on the implementation, the image signal processor 4030 may include fewer, more, or alternative modules.

In some embodiments, the angle information computation module 4031 may extract angle information based on the multiple angle views from the image sensing module 4020. For instance, the multiple angle views collected by each pixel group may include a top-left view, a top-right view, a bottom-left view, and a bottom-right view. The computation may be based on one or more combinations of two views selected from the top-left view, the top-right view, the bottom-left view, and the bottom-right view.

In some embodiments, the depth map construction module 4032 may be configured to construct a depth map based on the angle information computed by the angle information computation module 4031. For example, the depth map construction module 4032 may obtain a left view and a right view from the top-left view, the top-right view, the bottom-left view, and the bottom-right view as two views in stereo vision, and determine the disparity between the left view and the right view. Based on the disparity and the known position information of the pixels capturing the left and right views, the depth map construction module 4032 may generate the depth map. As another example, the left view and right view may be compensated with a top view and a bottom view from the top-left view, the top-right view, the bottom-left view, and the bottom-right view, and the depth map may be further computed based on the top view and the bottom view, along with the position information of the pixels captured the top and bottom views.

In some embodiments, the Bokeh effect rendering module 4033 may render the Bokeh effect to the target image based on the depth information. For instance, the depth information may reveal the foreground and the background of the target image. The Bokeh effect rendering module 4033 may perform linear filtering or nonlinear filtering to blur the background of the image depending on the depth of the background. Other methods for rendering the Bokeh effect may be contemplated.

In some embodiments, the resolution restoration module 4040 may be configured to restore the loss of resolution caused by the quad-pixel microlens. Using four contiguous pixels (a pixel group) to capture the same color (even though from multiple angle views) effectively reduces the resolution. To address this issue, linear or non-linear restoration algorithms may be executed to compensate for the lost resolution.

Embodiments of this application provide apparatuses, systems, and corresponding methods for using multi-pixel micro lenses to capture different angle views using a single image sensor. The described methods can be performed by hardware implemented on an ASIC or an FPGA as a part of the image sensor. With the disclosed image sensor, an apparatus, for example, a smart phone, may use a single image senor (i.e., a single camera) to capture depth information and render pictures with depth perception. The apparatus may also use more than one image sensors each being implemented as disclosed in this application. This configuration takes the advantage of the microlens refraction to obtain stereo vision views, without using multiple cameras/image sensors.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuit.

When the functions disclosed herein are implemented in the form of software functional units and sold or used as independent products, they can be stored in a processor executable non-volatile computer-readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, where the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain methods or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of example methods described herein may be performed, at least partially, by an algorithm. The algorithm may be comprised in program codes or instructions stored in a memory (e.g., a non-transitory computer-readable storage medium described above). Such algorithm may comprise a machine learning algorithm. In some embodiments, a machine learning algorithm may not explicitly program computers to perform a function but can learn from training data to make a prediction model that performs the function.

The various operations of example methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or sections of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. An image sensor apparatus, comprising:
a pixel array including a plurality of pixel groups, each pixel group having a square shape comprising at least four pixels, each pixel group being covered by a microlens with a curved surface and configured with color filters of a same color such that pixels in the pixel group capture the same color, wherein pixels in each pixel group capture different views of a scene as a result of refractions at the curved surface of the microlens; and
one or more processors electrically coupled to the pixel array and configured to:
compute a depth map of the scene based on the different views of the scene; and
render bokeh-effect to the scene based on the depth map.

2. The image sensor apparatus of claim 1, wherein every four adjacent pixel groups form a two-by-two matrix and the four adjacent pixel groups include at least three pixel groups configured with color filters of three different colors.

3. The image sensor apparatus of claim 1, wherein the plurality of pixel groups are configured with color filters arranged in a Bayer pattern such that every two-by-two matrix of pixel groups comprises two pixel groups configured with green filters, one pixel group configured with red filters, and one pixel group configured with blue filters.

4. The image sensor apparatus of claim 1, wherein the one or more processors are further configured to execute a resolution restoration algorithm to restore resolution loss caused by using multiple pixels in each pixel group to capture a same color.

5. The image sensor apparatus of claim 1, wherein each pixel group comprises two-by-two pixels, and the different views comprise a top-left view, a top-right view, a bottom-left view, and a bottom-right view.

6. The image sensor apparatus of claim 5, wherein to compute the depth map, the one or more processors are further configured to:
compute the depth map based on one or more combinations of two views from the top-left view, the top-right view, the bottom-left view, and the bottom-right view.

7. The image sensor apparatus of claim 5, wherein to compute the depth map, the one or more processors are further configured to:
obtain a left view and a right view from the top-left view, the top-right view, the bottom-left view, and the bottom-right view as two views in stereo vision;
determine a disparity between the left view and the right view; and
generate depth information based on the disparity and position information of the pixels that captured the left view and the right view.

8. The image sensor apparatus of claim 5, wherein to compute the depth map, the one or more processors are further configured to:
obtain a top view and a bottom view from the top-left view, the top-right view, the bottom-left view, and the bottom-right view as two views in stereo vision;
determine a disparity between the top view and the bottom view; and
generate depth information based on the disparity and position information of the pixels that captured the top view and the bottom view.

9. The image sensor apparatus of claim 1, wherein to render bokeh-effect based on the depth map, the one or more processors are configured to:
determine a foreground and a background of the scene; and
performing linear or non-linear filtering to blur the background of the scene depending on the depth of the background.

10. The image sensor apparatus of claim 1, wherein the image sensor apparatus is a smartphone camera.

11. An image sensor apparatus, comprising:
a pixel array including a plurality of pixel groups, each pixel group having a square shape comprising at least four pixels, wherein:
each pixel group is covered by a microlens;
each pixel group is configured with color filters of a same color such that pixels in the pixel group capture the same color; and
every four adjacent pixel groups form a two-by-two matrix and the four adjacent pixel groups include at least three pixel groups configured with color filters of three different colors.

12. The image sensor apparatus of claim 11, wherein:
the pixels in the pixel group are configured to capture different views of a scene as a result of refractions at a curved surface of the microlens; and
the image sensor apparatus further comprises:
one or more processors configured to compute depth information based on the different views captured by the pixels covered by the same microlens.

13. The image sensor apparatus of claim 12, wherein the different views comprise a top-left view, a top-right view, a bottom-left view, and a bottom-right view.

14. The image sensor apparatus of claim 13, wherein to compute the depth information, the one or more processors are further configured to:
compute the depth information based on one or more combinations of two views from the top-left view, the top-right view, the bottom-left view, and the bottom-right view.

15. The image sensor apparatus of claim 12, wherein the one or more processors are further configured to:
render bokeh-effect based on the depth information.

16. The image sensor apparatus of claim 15, wherein to render bokeh-effect based on the depth information, the one or more processors are configured to:
determine a foreground and a background of the scene; and
performing linear filtering to blur the background of the scene depending on a depth of the background.

17. The image sensor apparatus of claim 11, wherein the square shape comprises a side dimension of t, where t is equal to or greater than two.

18. The image sensor apparatus of claim 11, wherein the microlens comprises a curved surface and a plane surface, and the pixels in the pixel group covered by the microlens are evenly distributed under the plane surface.

19. The image sensor apparatus of claim 11, wherein the plurality of pixel groups are configured with color filters arranged in a Bayer pattern such that every two-by-two matrix of pixel groups comprises two pixel groups configured with green filters, one pixel group configured with red filters, and one pixel group configured with blue filters.

20. The image sensor apparatus of claim 11, further comprising:
one or more processors configured to execute a resolution restoration algorithm to restore resolution loss caused by using multiple pixels in each pixel group to capture a same color.
